(19) United States
(12) Patent Application Publication
(10) Pub. No.: US 2006/0046460 A1
(43) Pub. Date: Mar. 2, 2006

(54) METHOD OF FABRICATING POLY-CRYSTAL ITO FILM AND POLYCRYSTAL ITO ELECTRODE

(76) Inventor: Fang-An Shu, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/711,864

(22) Filed: Oct. 11, 2004

(30) Foreign Application Priority Data
Aug. 30, 2004 (TW) 93125996

(51) Int. Cl. H01L 21/44

(52) U.S. Cl. 438/608; 438/609; 438/663

(57) ABSTRACT

A method of fabricating a poly-crystal ITO thin film is provided. First, an amorphous ITO thin film is formed on a substrate. Then, a rapid thermal annealing process is performed to transform the amorphous ITO thin film into a poly-crystal ITO thin film. A method of fabricating a poly-crystal ITO electrode is further provided. First, an amorphous ITO thin film is formed on a TFT array substrate. Then, the amorphous ITO thin film is patterned to form a plurality of amorphous ITO electrodes. A rapid thermal annealing process is performed to transform the amorphous ITO electrodes into a plurality of poly-crystal ITO electrodes. A poly-crystal ITO thin film with improved planarity is formed. Processing time is reduced and throughput of the process is then improved.

### CROSS-REFERENCE TO RELATED APPLICATION

This application claims the priority benefit of Taiwan application No. 93125996, filed on Aug. 30, 2004.

### BACKGROUND OF THE INVENTION

1. Field of Invention

The present invention relates to fabrication of indium tin oxide (ITO) film and transparent electrode. More particularly, the present invention relates to method for fabricating a poly-crystal ITO film and a poly-crystal ITO electrode.

2. Description of Related Art

Display terminal is the communication interface between user and information media. Currently, the panel display is the trend in development. The panel display mainly includes organic electro-luminescence display (OELD), plasma display panel (PDP), liquid-crystal display (LCD), and light emitting diode (LED), and so on. The ITO transparent conductive film plays an important role in the above displays. The ITO film not only is used as the transparent electrode material in good conductivity, but also can be used in various applications in heating, thermal reflection, shielding of electromagnetic wave, anti-electrostatic charges, and so on. Thus, ITO film can have various applications in different types of displays in TFT array, color filter, LED, organic electro-luminescence display, or PDP.

However, the surface planarity of the ITO film would definitely affect the stability of the device. Taking the organic electro-luminescence display as the example, if the surface planarity of the ITO film is relative large, the cathode layer (if the ITO is the anode) then is easy to have an approach to the protrusion part of the ITO film. This would cause a high local electric filed on the electrode surface, and then cause a large current to flow over this local area. When a larger current flows through this local area, the temperature at this local area increases, and it then results in melting at the local area. This causes the damages on the organic electro-luminescence display.

Therefore, in order to have better film properties for the ITO material, such as the surface planarity or resistance, the conventional technology usually includes an annealing process after forming the film. The conventional annealing process is using oven or heating plate to anneal the amorphous ITO film, so as to transform into poly-crystal ITIO film. However, the procedures for increasing temperature, maintaining the temperature (200° C.), and decreasing the temperature take a long time, in which the fabrication time usually lasts for few hours, and are therefore not good for increasing the throughput.

Another conventional annealing process is using the ultraviolet (UV) light to illuminate on the amorphous ITO film, so as to transform into the poly-crystal ITO film. Since the energy by using the UV light is less, after illumination from UV light, it still needs the oven to perform a post annealing process on the ITO film. In general, the time for annealing process is not reduced.

In order to reduce the annealing time, the U.S. Pat. No. 6,448,158 has proposed a method of patterning an ITO layer. In U.S. Pat. No. 6,448,158, it mainly uses the excimer laser annealing (ELA) to transform the amorphous ITO film into poly-crystal ITO film. However, since the laser beam has the limitation for the illumination area, if it is used in annealing for the large area, it is not easy to control to have the uniform thickness for the film being formed. In addition, the expensive laser annealing equipment also cause the increase of fabrication cost, and manufacturers in competition would decrease.

### SUMMARY OF THE INVENTION

For an object, the invention provides a method for fabricating ITO film, suitable for forming a poly-crystal ITO film with better film properties, and reducing the fabrication time and cost.

For another object, the invention provides a method for fabricating ITO electrode, suitable for forming the poly-crystal ITO electrode with high stability, and reducing the fabrication time and cost.

The invention provides a method for fabricating ITO film. At first, an amorphous ITO film is formed on a substrate. A rapid thermal annealing (RTA) process is performed, to transform the amorphous ITO film into a poly-crystal ITO film.

In a preferred embodiment of the invention, the process to form the amorphous ITO film includes, for example, sputtering or other method such as physical vapor deposition, or chemical vapor deposition. In addition, in the embodiment, the thickness of the amorphous ITO film is, for example, 400-1500 angstroms. The RTA process is in operation, for example, under 400° C.-700° C. for 0.5-6 minutes.

The invention also provides a method for fabricating ITO electrode, suitable for forming a transparent electrode in a TFT-array, a color filter, an LED, an organic electro-luminescence display, or a PDP. The method for fabricating ITO electrode includes that an amorphous ITO film is formed on a substrate. The amorphous ITO film is patterned to form multiple amorphous ITO electrodes on the substrate. Then, a rapid thermal annealing process is performed, to transform the amorphous ITO electrodes into multiple poly-crystal ITO electrodes.

In a preferred embodiment of the invention, the process to form the poly-crystal ITO electrodes include, for example, sputtering or other method such as physical vapor deposition or chemical vapor deposition. In addition, in the embodiment, the thickness of the amorphous ITO film is, for example, 400-1500 angstroms. The RTA process is in operation, for example, under 400° C.-700° C. for 0.5-6 minutes.

In the embodiment of the invention, the process for patterning the amorphous ITO film includes, for example, forming a patterned photoresist layer over the amorphous ITO film. Then, a portion of the amorphous ITO film is removed by using the photoresist layer as the mask. In accordance, the amorphous ITO film is removed by, for example, oxalic acid or other etchants, so that multiple amorphous ITO electrode on the substrate. Then, the photoresist layer is removed.

In the preferred embodiment of the invention, the foregoing substrate includes glass substrate, silicon substrate, or plastic substrate.

In the preferred embodiment of the invention, the foregoing substrate includes rigid substrate or flexible substrate.

In the invention, the RTA is used, so that the amorphous ITO film can be rapidly transformed into poly-crystal ITO film. This can reduce the fabrication time and can improve the throughput. The poly-crystal ITO film being formed has better film properties, such as the surface planarity or the electric resistance.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a drawing, schematically illustrating the fabrication processes for the poly-crystal ITO film, according to a preferred embodiment of the invention.

FIGS. 2A-2D are cross-sectional views, schematically illustrating the fabrication processes for the poly-crystal ITO film, according to a preferred embodiment of the invention.

FIG. 3 is a drawing, schematically illustrating the fabrication processes for the poly-crystal ITO electrode, according to a preferred embodiment of the invention.

FIGS. 4A-4H are cross-sectional views, schematically illustrating the fabrication processes for the poly-crystal ITO electrode, according to a preferred embodiment of the invention.

FIGS. 5A-5E is a drawing, schematically illustrating the various applications of the ITO electrode.

### DESCRIPTION OF THE PREFERRED EMBODIMENTS

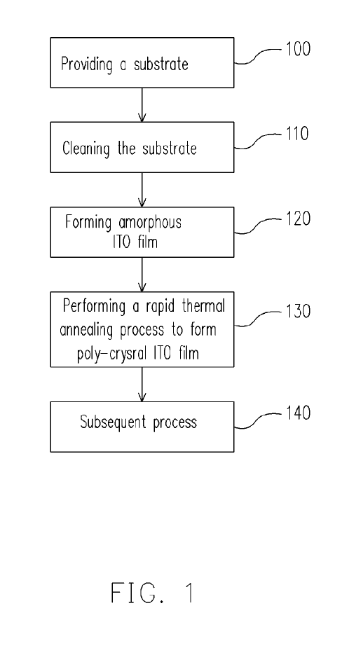

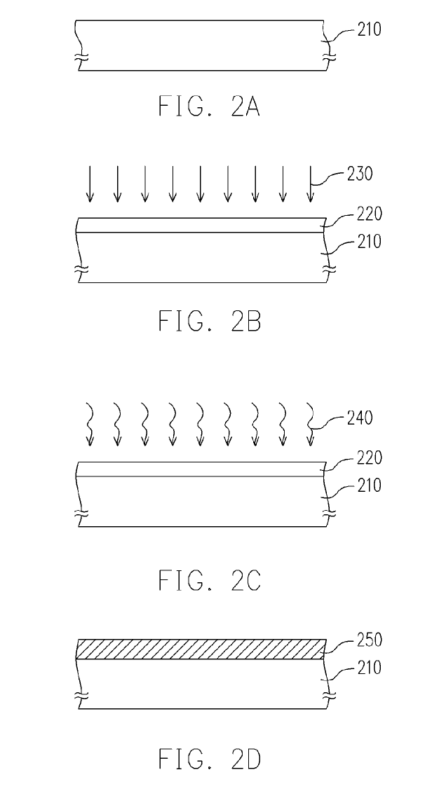

FIG. 1 is a drawing, schematically illustrating the fabrication processes for the poly-crystal ITO film, according to a preferred embodiment of the invention. FIGS. 2A-2D are cross-sectional views, schematically illustrating the fabrication processes for the poly-crystal ITO film, according to a preferred embodiment of the invention.

In FIG. 1 and FIG. 2A, a substrate 210 is provided (step 100). And before forming the ITO film, a cleaning process (step 110) is performed on the substrate 210, so as to remove the contamination material or particles on the substrate 210. In the embodiment, the substrate 210 includes, for example, glass substrate, silicon substrate, plastic substrate, or other rigid substrate or flexible substrate.

Then, as shown in FIG. 1 and FIG. 2B, an amorphous ITO film 220 is formed on the substrate 210 (step 120). Accordingly, the method to form the amorphous ITO film 220 includes, for example, physical vapor deposition (PVD) or chemical vapor deposition (CVD). In the embodiment of the invention, the formation of the amorphous ITO film 220 is, for example, the sputtering process, which uses the target of ITO material to form the target ions 230. The sputtering process causes the target ions 230 to be deposited on the substrate 210 to form the amorphous ITO film 220. The thickness of the amorphous ITO film 220 is, for example, between 400-1500 angstroms. In the preferred embodiment, the thickness of the amorphous ITO film 220 is about 500 angstroms.

As shown in FIG. 1 and FIG. 2C, a rapid thermal annealing (RTA) process 240 is performed for heating the amorphous ITO film 220, so as to transform into poly-crystal ITO film 250 (step 130). Since the electric resistance, the crystal structure, surface planarity, or the stress of the crystal of the amorphous ITO film 220 is not optimized, the annealing process is necessary to transform into the poly-crystal ITO film 250. The RTA process used in the embodiment can raise the temperature of the reaction chamber to the reaction temperature in a short time period, and rapidly decrease to the original temperature after the reaction. In the embodiment of the invention, the amorphous ITO film 220 formed on the substrate 210 is operated under an annealing temperature of 400° C.-700° C. with 0.5-6 minutes, and then it can be transformed into poly-crystal ITO film 250. In another embodiment, the RTA process is, for example, operated at 600° C. with 1 minute, so as to obtain good film properties as the poly-crystal ITO film 250.

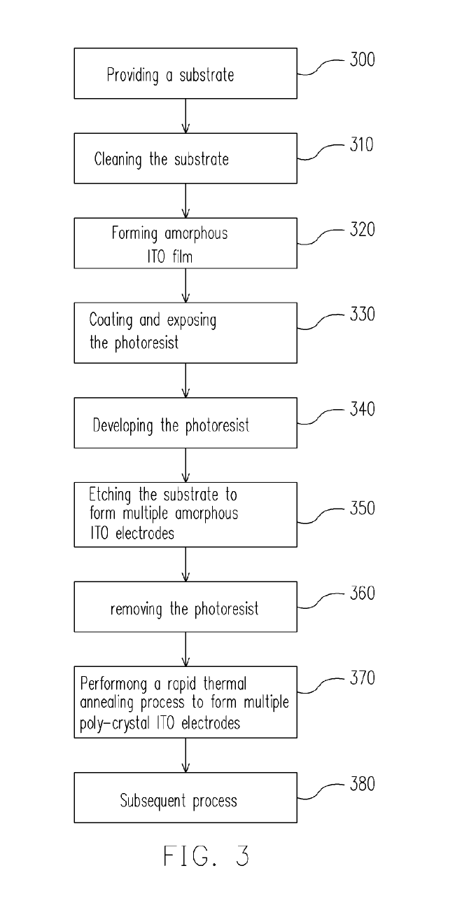

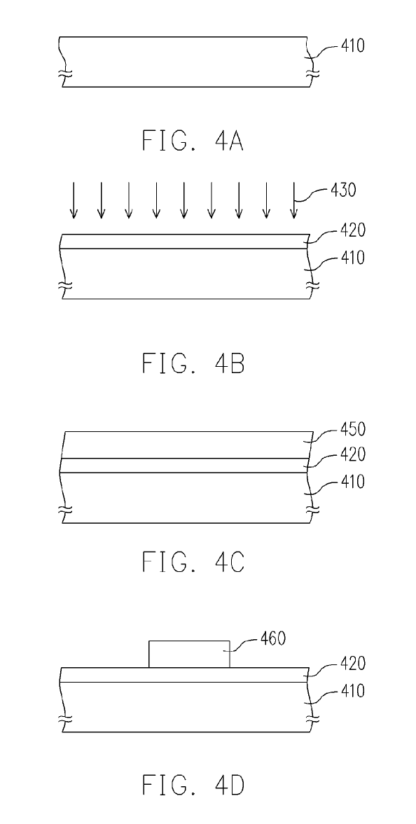

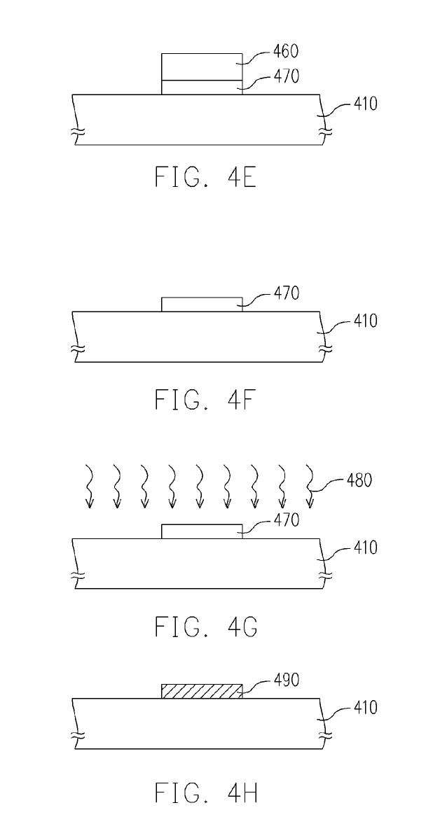

FIG. 3 is a drawing, schematically illustrating the fabrication processes for the poly-crystal ITO electrode, according to a preferred embodiment of the invention. FIGS. 4A-4H are cross-sectional views, schematically illustrating the fabrication processes for the poly-crystal ITO electrode, according to a preferred embodiment of the invention.

As shown in FIG. 3 and FIG. 4A, a substrate 410 is provided (step 300), which is used to performing the process for forming the amorphous ITO film. In the embodiment, the substrate 410 includes, for example, glass substrate, silicon substrate, plastic substrate, or other rigid substrate or flexible substrate. Before forming the amorphous ITO film, the substrate 410 is cleaned (step 310) for remove the contamination material or particles. Then, as shown in FIG. 3 and FIG. 4G, the substrate 410 form an amorphous ITO film 420 (step 320). In the embodiment, the method to form the amorphous ITO film 420 includes, for example, physical vapor deposition (PVD) or chemical vapor deposition (CVD). In the embodiment of the invention, the formation of the amorphous ITO film 420 is, for example, the sputtering process, which uses the target of ITO material to form the target ions 430. The sputtering process causes the target ions 430 to be deposited on the substrate 410 to form the amorphous ITO film 420. The thickness of the amorphous ITO film 420 is, for example, between 400-1500 angstroms. In the preferred embodiment, the thickness of the amorphous ITO film 420 is about 500 angstroms.

Then, the amorphous ITO film 420 is patterned to form multiple amorphous electrodes 470 on the substrate 410.

As shown in FIG. 3 and FIG. 4C, a photoresist layer 450 is coated on the amorphous ITO film 420, and the photoresist layer 450 is exposed (step 330). Then, in FIG. 3 and FIG. 4D, the photoresist layer 450 is developed, so that the photoresist layer 450 is patterned to form the patterned photoresist layer 460 (step 340). Then, in FIG. 3 and FIG. 4E, the patterned photoresist layer 460 is used as the mask, so that a portion of the amorphous ITO film 420 is removed, and multiple amorphous ITO electrodes 470 are formed on the substrate 410 (step 350). In the preferred embodiment, for example, the oxalic acid is used as the etchant to perform wet etching, for removing the portion of the amorphous ITO film 420. Other etchants with capability to etch the amorphous ITO film 420 can also be used. Then, in FIG. 3 and FIG. 4F, the patterned photoresist layer 460 is stripped, and the amorphous ITO electrodes 470 remain on the substrate (step 360).

As shown in FIG. 3 and FIG. 4G, a RTA process 480 is performed to heat the amorphous ITO electrodes 470, and to transform into multiple poly-crystal ITO electrodes 490 (step 370). In this embodiment, the RTA process can be, for example, operated under a temperature of 400° C.-700° C. for 0.5-6 minutes, so that the amorphous ITO electrodes 470 can be transformed into multiple poly-crystal ITO electrodes 490. In a preferred embodiment, the RTA process can be, for example, operated under a temperature of 600° C. for 1 minute, as to obtain the multiple poly-crystal ITO electrodes 490 with better film properties, such as electric resistance, surface planarity, crystal structure, or electron mobility. This can allow a more stable operation condition for the subsequent device.

As shown in FIG. 3 and FIG. 4H, the poly-crystal ITO electrodes 490 can be performed with the subsequent processes (step 380), for applying the transparent electrode to various types of panel display.

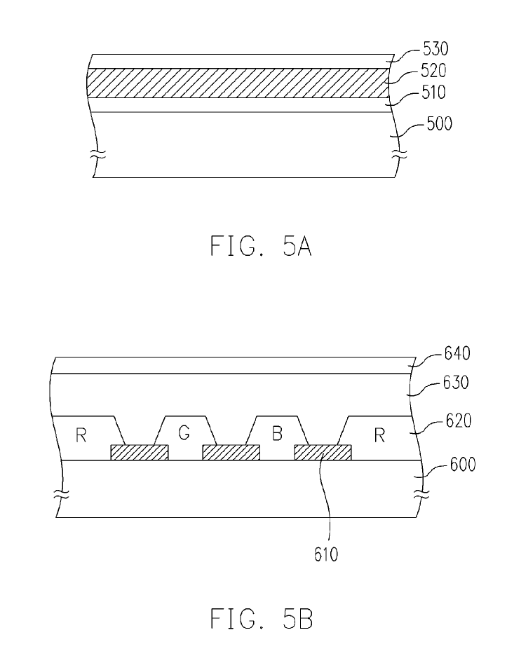

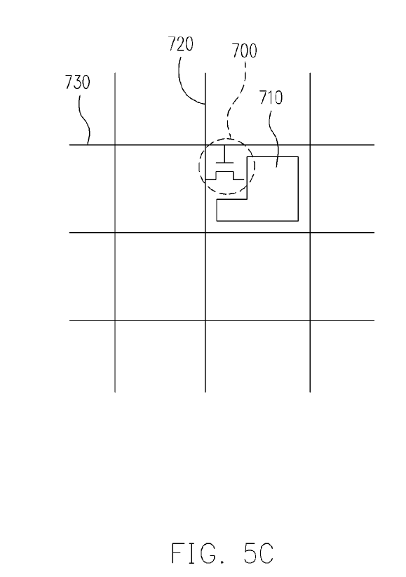

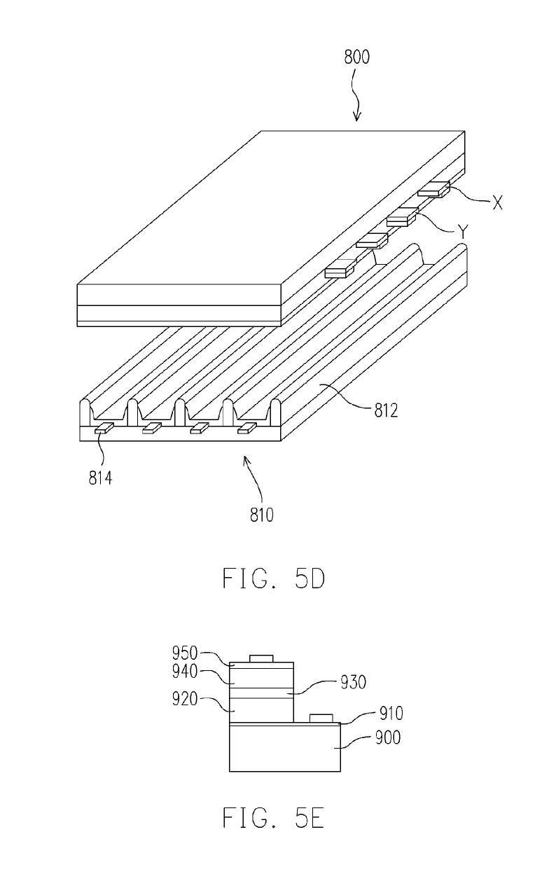

FIG. 5A-5E is a drawing, schematically illustrating the various applications of the ITO electrode. In FIG. 5A, an organic electro-luminescence display includes a substrate 500, an anode 510, an organic light emitting layer 520, and a cathode 530. In the organic electro-luminescence display, the anode 510 can be formed by using the method for fabricating the ITO film of the invention.

The method for fabricating the ITO film of the invention can also be applied in a usual LCD, such as the color filter shown in FIG. 5B and TFT-array shown in FIG. 5C. In FIG. 5B, the color filter at least includes a substrate 600, multiple light shielding layer 610, and multiple color filtering films 620, a protection layer 630 and a common electrode 640. In the color filter, the common electrode 640 can be formed by using the method for fabricating the ITO film of the invention. In FIG. 5C, the TFT-array includes at least multiple TFT's 700, a pixel electrode 710, data lines 720, and scan line 730, wherein the pixel electrode 710 can be formed by using the method for fabricating the ITO film of the invention.

In a large-size display, taking the PDP as an example in FIG. 5D, the PDP is, for example, composed of a front substrate 800 and a rear substrate 810. The front substrate 800 at least includes X electrode and Y electrode Y. The rear substrate 810 ate least includes rib 812 and address electrode 814. Wherein, the X electrode and the Y electrode can be formed by using the method for fabricating the ITO film of the invention.

In LED display, it also has the application of ITO film. As shown in FIG. 5E, the LED includes at least a substrate 900, a cathode 910, an n-type semiconductor layer 920, a light emitting layer 930, a p-type semiconductor layer 940, and an anode 950, wherein the cathode 910 or the anode 950 can be the transparent ITO film. This cathode 910 or anode 950 can be formed by using the method for fabricating the ITO film of the invention.

In summary, the method of fabricating poly-crystal ITO film and poly-crystal ITO electrode in the invention has at least the advantages as follows:

The invention uses the RTA process in forming the ITO film. It has the advantages of reducing the fabrication time is reduced, increasing the throughput, and reducing the fabrication cost.

The invention can form the ITO film with good properties. In addition to better film planarity, the ITO film can be used in the subsequent fabrication process, and then the operation can be more stable.

The method of fabricating poly-crystal ITO film of the invention can be applied to various panel display for fabrication of film or electrode.

It will be apparent to those skilled in the art that various modifications and variations can be made to the structure of the present invention without departing from the scope or spirit of the invention. In view of the foregoing descriptions, it is intended that the present invention covers modifications and variations of this invention if they fall within the scope of the following claims and their equivalents.

1. A method for fabricating poly-crystal indium tin oxide (ITO) film, the method comprising:
forming an amorphous ITO film on a substrate; and
performing one rapid thermal annealing (RTA) process, to transform the amorphous ITO film into a poly-crystal ITO film.

2. The method of claim 1, wherein the step of forming the amorphous ITO film includes sputtering, physical vapor deposition, or chemical vapor deposition.

3. The method of claim 1, wherein a thickness of the amorphous ITO film is 400-1500 angstroms.

4. The method of claim 1, wherein the RTA process is operated under 400° C.-700° C. for 0.5-6 minutes.

5. The method of claim 1, wherein the substrate includes glass substrate, silicon substrate, or plastic substrate.

6. The method of claim 1, wherein substrate includes rigid substrate or flexible substrate.

7. A method for fabricating poly-crystal indium tin oxide (ITO) electrode, suitable for use to form electrodes in a thin film transistor array, a color filter, a light emitting diode, or an organic electro-luminescence display, the method comprising:
forming an amorphous ITO film on a substrate;
patterning the amorphous ITO film, to form a plurality of amorphous ITO electrodes on the substrate; and
performing one rapid thermal annealing (RTA) process, to transform the amorphous ITO electrodes into a plurality of poly-crystal ITO electrodes.

8. The method of claim 7, wherein the step of forming the amorphous ITO film includes sputtering, physical vapor deposition, or chemical vapor deposition.

9. The method of claim 7, wherein a thickness of the amorphous ITO electrode is 400-1500 angstroms.

10. The method of claim 7, wherein the step of patterning the amorphous ITO film includes:
forming a patterned photoresist layer on the amorphous ITO film;
removing a portion of the amorphous ITO film by using the photoresist layer as the pattern as a mask, so as to form the amorphous ITO electrodes on the substrate; and
removing the photoresist layer.

11. The method of claim 10, wherein the portion of the amorphous ITO film is removed by oxalic acid.

12. The method of claim 7, wherein the RTA process is operated under 400° C.-700° C. for 0.5-6 minutes.

13. The method of claim 7, wherein the substrate includes glass substrate, silicon substrate, or plastic substrate.

14. The method of claim 7, wherein substrate includes rigid substrate or flexible substrate.
